(19) United States
(12) Patent Application Publication
(10) Pub. No.: US 2008/0274896 A1
(43) Pub. Date: Nov. 6, 2008

(54) Substrate for Superconducting Wire and Fabrication Method Thereof and Superconducting Wire

(76) Inventors: Bong-Ki Ji, Gyeonggi-do (KR); Byoung-Kwang Lee, Gyeonggi-do (KR)

Correspondence Address: STROOCK & STROOCK & LAVAN LLP, 180 MAIDEN LANE, NEW YORK, NY, 10038, US

(21) Appl. No.: 11/913,829

(22) PCT Filed: Sep. 5, 2005
(86) PCT No.: PCT/KR05/02935

§ 371 Date: Jun. 3, 2008

(30) Foreign Application Priority Data
Aug. 30, 2005 (KR) 10-2005-0079821

(51) Int. Cl. H01L 39/00; H01L 39/24

(52) U.S. Cl. 505/124; 505/433

(57) ABSTRACT

A substrate for a superconducting wire is made of Ni or Ni alloy, with a ratio of cube texture of 95% or above constant in a width direction of a substrate body, a ratio of low-angle (15 or less) grain boundary of 99% or above regularly distributed in the width direction, a thickness of 40-150 μm, an average grain size of 100 μm or less, and a surface roughness of RMS 50 nm or less. A method for fabricating the substrate includes rolling a Ni or Ni-alloy rod with a rectangular section; and thermally treating the rolled rod, the rolling step having a reduction ratio of 5 to 15% at each rolling, the rod being moved between rollers for the rolling process at a linear velocity of 100 m/min or less, the thermally treating process being conducted by heating above a recrystallization temperature with flowing an inert gas including hydrogen gas.

### TECHNICAL FIELD

The present invention relates to a superconducting wire, and more particularly to a substrate for a superconducting wire having a quantified substrate feature to prevent generation of cracks or anisotropic crystals, a fabrication method of the substrate, and a superconducting wire fabricated by the method.

### BACKGROUND ART

A superconducting wire may be classified into a first-generation BSCCO (Bi—Sr—Ca—Cu—O) wire and a second-generation YBCO (Y—Ba—Cu—O). In particular, the second-generation superconducting film wire is expected to be widely used for SuperVAR™, motor, power generator, power cable, magnetic propulsion ship, MRI and so on since it is relatively cheap and has strong tolerance to high magnetic fields.

Generally, the second-generation superconducting film wire (hereinafter, referred to as ‘superconducting wire’) includes a substrate 11, a buffer layer 12, a superconducting layer 13 and a protective layer 14 as shown in FIG. 1. The substrate 11 is processed in a way of rolling and thermally treating a metal material to form a cube texture, and the buffer layer 12 and the superconducting layer 13 are epitaxially laminated thereon in various ways. In addition, the protective layer 14 is made of a metal material with a relatively low electric resistance in order to protect the wire when an overcurrent flows therein.

Here, the substrate 11 is particularly important in deciding performance and quality of the superconducting wire due to its features, so it is very important to optimally quantify structural features of the substrate 11. For example, if a ratio of cube texture of the substrate 11 is low, the buffer layer 12 grown thereon has a deteriorated degree of texture or is grown in different directions, and a crack may be generated at a portion where a grain boundary angle is great. In addition, in case the ratio of cube texture and the grain boundary angle are irregular, performance and quality of the superconducting layer are deteriorated.

When regulating the features of a substrate for a superconducting wire in the prior art, a cube texture was scanned using X-ray to quantify only FWHM (Full Width at Half Maximum), so that FWHM represents all features of the substrate. However, FWHM may have a good value even when a ratio of cube texture is seriously low and a grain boundary angle is great, and in this case it is impossible to obtain a high-quality superconducting wire. Thus, there is needed to research quantification of features of a substrate in more various ways.

### DISCLOSURE OF INVENTION

### Technical Problem

The present invention is designed in consideration of the above problems, and there fore it is an object of the invention to provide a substrate for a superconducting wire in which substrate features such as a grain boundary angle, a ratio of cube texture, a surface roughness, grain size and so on are quantified to prevent generation of a crack or an anisotropic crystal, a fabrication method thereof, and a superconducting wire fabricated therefrom.

### Technical Solution

In order to accomplish the above object, the present invention provides a substrate for a superconducting wire, wherein the substrate is made of Ni or Ni alloy, wherein the substrate has a ratio of cube texture of 95% or above, which is constant in a width direction of a body of the substrate, wherein the substrate has a ratio of low-angle (not greater than 15 degrees) grain boundary of 99% or above, whose distribution is regular in the width direction of the body of the substrate, wherein the substrate has a thickness of 40 to 150□, wherein the substrate has an average grain size of 100□ or less, and wherein the substrate has a surface roughness of RMS (Root Mean Square) 50 nm or less.

Preferably, the Ni alloy contains Co, Cr, V, Mo, W or B.

In another aspect of the present invention, there is provided a method for fabricating a substrate for a superconducting wire, which includes rolling a Ni or Ni-alloy rod with a rectangular section; and thermally treating the rolled Ni or Ni-alloy rod, wherein the rolling step has a reduction ratio of 5 to 15% at each rolling, wherein the rod is moved between rollers for the rolling process at a linear velocity of 100 m/min or less, and wherein the thermally treating process is conducted by heating at a temperature over a recrystallization temperature together with flowing an inert gas including hydrogen gas.

Preferably, the insert gas includes the hydrogen gas at the content of 3 to 5%.

In still another aspect of the present invention, there is also provided a super-conducting wire, which includes a substrate made of Ni or Ni alloy and having a ratio of cube texture of 95% or above, which is constant in a width direction of the substrate, a ratio of low-angle (not greater than 15 degrees) grain boundary of 99% or above, whose distribution is regular in the width direction of the substrate, a thickness of 40 to 150□, an average grain size of 100□ or less, and a surface roughness of RMS 50 nm or less; at least one buffer layer epitaxially laminated on the substrate; and a super-conducting layer epitaxially laminated on the buffer layer.

The buffer layer may be composed of ZrO₂, CeO₂, YSZ, Y₂O₃ or HfO₂.

As an alternative, the buffer layer may have three layers laminated from a surface of the substrate in the order of CeO₂, YSZ and CeO₂.

As another alternative, the buffer layer may have three layers laminated from a surface of the substrate in the order of Y₂O₃, YSZ and CeO₂.

As still another embodiment, the buffer layer may also be three layers laminated from a surface of the substrate in the order of CeO₂, YSZ and Y₂O₃.

### BRIEF DESCRIPTION OF THE DRAWINGS

These and other features, aspects, and advantages of preferred embodiments of the present invention will be more fully described in the following detailed description, taken accompanying drawings. In the drawings:

FIG. 1 is a sectional view showing a conventional superconducting wire;

FIG. 2 is a SEM (Scanning Electron Microscope) photograph obtained by observing a surface state of a substrate for a superconducting wire according to the present invention;

FIG. 3 is a photograph showing the substrate of FIG. 2, which is visually improved using EBSD (Electron Back Scattering Diffraction);

FIG. 4 is a photograph obtained by observing a cube texture of the substrate of FIG. 2 using EBSD;

FIG. 5 is a graph showing a ratio of cube texture corresponding to a processing pattern of a substrate according to the present invention;

FIG. 6 is a photograph and a graph showing a measurement result of a grain boundary angle using EBSD;

FIG. 7 is a photograph and a graph showing a measurement result of a grain size for a Ni substrate;

FIG. 8 is a graph showing a measurement result of a grain size for a Ni substrate to which tungsten W is added;

FIG. 9 is a diagram showing a rolling process for processing a substrate for a super-conducting wire according to the present invention;

FIG. 10 is a diagram showing a rolling process for processing a conventional substrate for a superconducting wire;

FIG. 11 is a 3-dimensional graph showing a surface roughness analysis result of a substrate using AFM (Atomic Force Microscope);

FIG. 12 is a sectional view showing a superconducting wire according to one embodiment of the present invention; and

FIG. 13 is a sectional view showing a superconducting wire according to another embodiment of the present invention.

### BEST MODE FOR CARRYING OUT THE INVENTION

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation. Therefore, the description proposed herein is just a preferable example for the purpose of illustrations only, not intended to limit the scope of the invention, so it should be understood that other equivalents and modifications could be made thereto without departing from the spirit and scope of the invention.

A substrate for a superconducting wire according to the present invention is made of Ni or Ni alloy, whose ratio of cube texture is 95% or above and ratio of low-angle grain boundary is 99% or above, wherein the ratio of cube texture and the distribution of low angle grain boundary are constant in a width direction of the substrate body. In addition, the substrate has a thickness of 40 to 150□, an average grain size of 100□ or below, and a surface roughness of 50 nm or less in RMS (Root Mean Square).

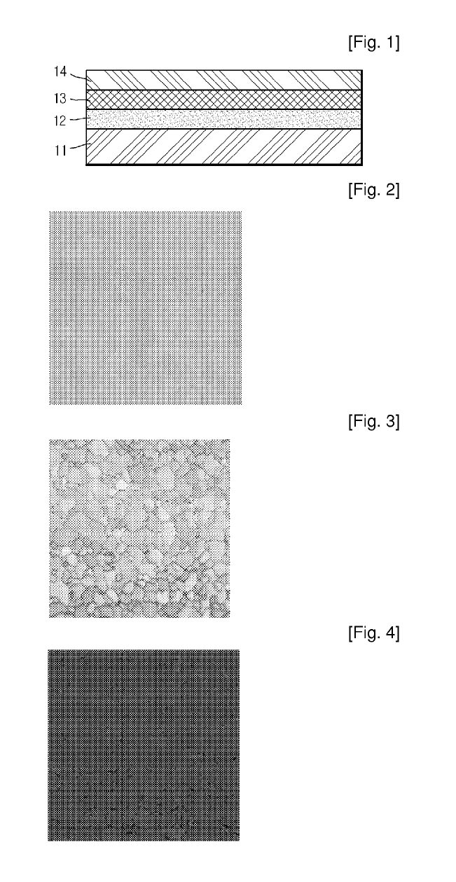

FIG. 2 shows a state of a substrate surface on which a buffer layer is to be deposited, observed using SEM, and FIG. 3 shows a substrate state of FIG. 1, which is more visually improved using EBSD. In addition, FIG. 4 shows a cube texture observed in a normal direction of the substrate using EBSD.

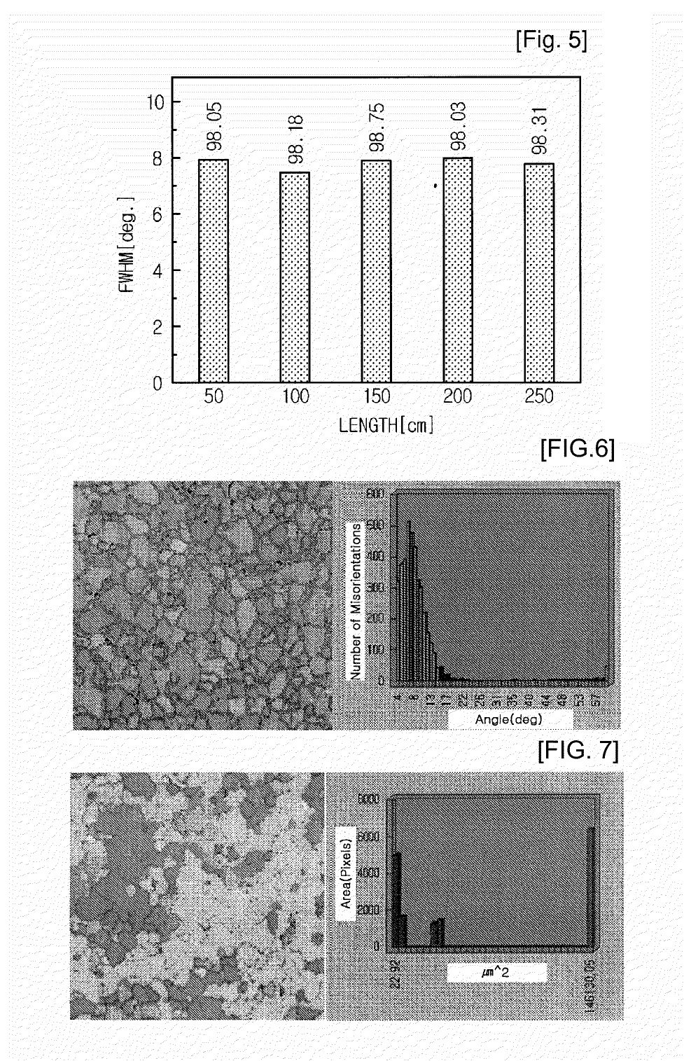

Referring to FIGS. 2 to 4, it would be understood that the substrate for a super-conducting wire according to the preferred embodiment of the present invention has a cube texture well developed in a normal direction of the substrate, and the degree of texture is very high. More quantitatively, FIG. 5 shows a ratio of cube texture corresponding to processing patterns of the substrate with different lengths and FWHM (Full Width at Half Maximum) as a numerical value. As shown in FIG. 5, it would be understood that the ratio of cube texture is regularly distributed within the range of 95% or above without a great change according to the processing pattern.

FIG. 6 shows a measurement result of a grain boundary angle using EBSD. As shown in FIG. 6, it is checked that, in case of the substrate for a superconducting wire according to the preferred embodiment of the present invention, more than 99% of a misorientation angle of the grain boundary is a low-angle (15° or below) grain boundary.

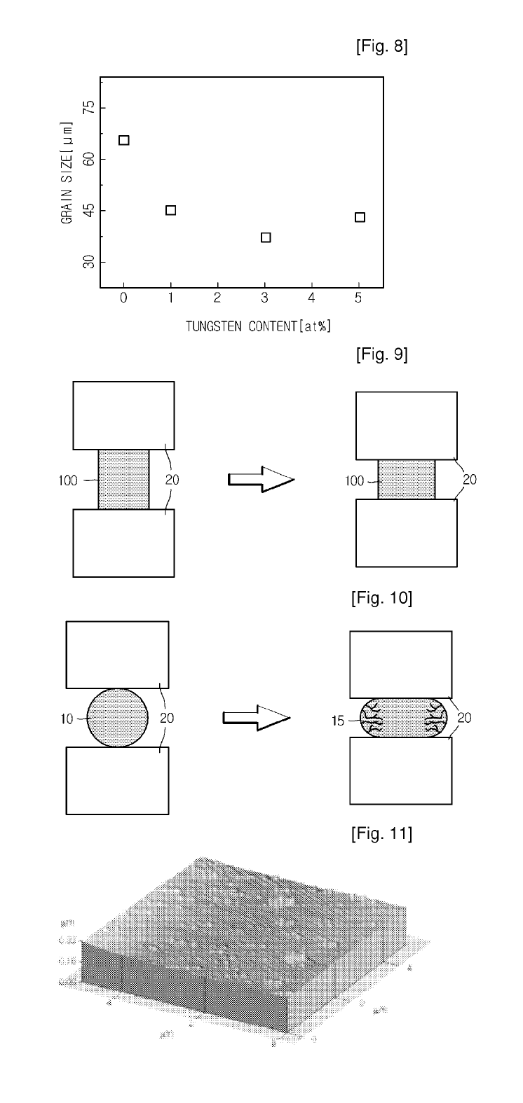

FIG. 7 shows a measurement result of a grain size of a Ni substrate, and FIG. 8 shows distribution of grain size measurement data of a Ni substrate to which tungsten W is added. As shown in FIG. 7, the substrate for a superconducting wire according to the preferred embodiment of the present invention is measured to have an average grain size of 70□, which does not exceed 150□. In addition, though an alloy element is contained as shown in FIG. 8, an average grain size is measured to be 35 to 75□, which does not exceed 150 □.

FIG. 9 schematically shows a rolling process, which is used for processing the substrate for a superconducting wire according to the present invention. As shown in FIG. 9, the substrate for a superconducting wire according to the present invention is obtained using a rolling process in which a Ni or Ni-alloy preform rod 100 with a rectangular section is passed between rollers 20. The substrate reduced in the rolling process as mentioned above has a final thickness of 40 to 150□. In particular, since the substrate for a superconducting wire according to the present invention is processed from the preform rod 100 with a rectangular section, no crack 15 occurs during the rolling process differently from the case using a preform rod 10 (see FIG. 10) with a circular section.

FIG. 11 shows a surface roughness analysis result of a substrate using AFM. As shown in FIG. 11, the substrate for a superconducting wire according to the preferred embodiment of the present invention has a surface roughness kept in 50 nm or below.

The substrate for a superconducting wire according to the present invention as configured above is fabricated using a process of rolling a Ni or Ni-alloy rod with a rectangular section and a process of thermally treating the rolled Ni or Ni-alloy rod.

In particular, the rolling process is executed to have a reduction ratio of 5 to 15% at each rolling, and a linear velocity of the rod between the rollers is set to be 100 m/min or less.

Preferably, the thermal treatment process is executed by heating at a temperature over a recrystallization temperature with flowing an inert gas including hydrogen gas thereto, and at this time the hydrogen gas is preferably included at the content of 3 to 5% so as to prevent oxidization of the substrate and enhance a reduction efficiency.

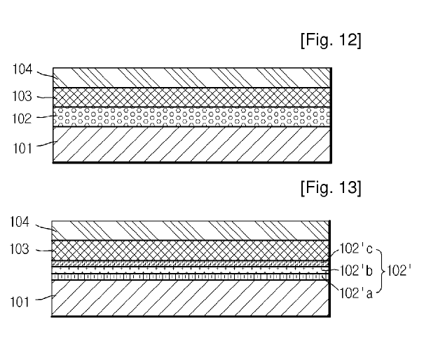

Meanwhile, FIG. 12 shows a superconducting wire provided according to a preferred embodiment of the present invention. Referring to FIG. 12, the super-conducting wire includes a substrate 101 made of Ni or Ni alloy, at least one buffer layer 102 epitaxially laminated on the substrate 101, and a superconducting layer 103 epitaxially laminated on the buffer layer 102. Here, the superconducting layer 103 may employ a general superconducting layer used in a common superconducting wire, and a protective layer 104 may be further provided on the superconducting layer 103 in order to protect the wire against overcurrent.

Identically to the above, the Ni or Ni-alloy substrate 101 is configured such that a ratio of cube texture is 95% or above, a ratio of low-angle grain boundary at 15 or below is 99% or above, and the ratio of cube texture and the low angle grain boundaries are regularly distributed in a width direction of the substrate body, wherein the substrate has a thickness of 40 to 150□, an average grain size of 100□ or below, and a surface roughness of RMS 50 nm or below.

The buffer layer 102 may be composed of a single layer made of ZrO₂, CeO₂, YSZ, Y₂O₃ or HfO₂.

As shown in FIG. 13, the buffer layer 102′ may include a first buffer layer 102′a made of CeO₂, a second buffer layer 102′b made of YSZ, and a third buffer layer 102′c made of CeO₂. Here, the first buffer layer 102′a, the second buffer layer 102′b and the third buffer layer 102′c are subsequently laminated on the substrate 101.

As an alternative, the first buffer layer 102′a, the second buffer layer 102′b and the third buffer layer 102′c may be respectively made of Y₂O₃, YSZ and CeO₂.

As another alternative, the first buffer layer 102′a, the second buffer layer 102′b and the third buffer layer 102′c may be composed of three layers laminated from the substrate surface in the order of CeO₂, YSZ and Y₂O₃.

### FABRICATION EXAMPLE

High-purity Ni powder (99.99%, 100 mesh, Aldrich Co.) was used to minimize any effect on formation of Ni texture caused by impurities. Ni powder has a rounded shape as a whole, and projections similar to a casting texture were observed on the power surface. The used powder grains had an average size of about 5 mm, and they had relatively uniform shapes and sizes. 40 g of Ni power was quantified in order to make a shaping body for fabricating a Ni substrate, and then the Ni powder was filled in a rubber mold (with a diameter of 10 mm). After the Ni powder was filled, the rubber mold was vacuum-packaged with a waterproof vinyl and then put into a hydraulic container, and then 200 MPa of hydrostatic pressure was applied to the hydraulic container to make a shaping body with a rod shape (with a diameter of 8.7 mm and a length of 132 mm). Then, the Ni rod separated from the rubber mold was sintered for 6 hours at 1100° C. under Ar-4% H₂ environment so as to make the Ni rod denser. At this time, a heating and cooling rate was set to 300° C./hr.

The sintered test pieces were cold-rolled into a thin tape shape between two-stage rollers having a reduction ratio of 10% at each rolling with the test pieces having a linear velocity of 10 m/min, and then a single-axis tensile stress was applied to the test pieces to induce uniform deformation. During the rolling process, an intermediate sintering step was conducted at a temperature over a recrystallization temperature of Ni so as to prevent a crack from being generated in the substrate.

The substrate had a final thickness of 100□ and a final width of 10 mm. The thermal treatment for recrystallization was conducted for 30 minutes at 1000° C., and the environment and the heating and cooling rate at this process were identical to those of the sintering process.

### Experimental Example 1

### Observation of Horizontal Level during Deposition depending on Thickness of Metal Tape and Cracks generated in the Upper Thin Film

Using the above fabricating method, substrates according to embodiments 1, 2, 3, 4 and 5 respectively having thickness of 40□, 70□, 100□, 120□ and 150□ and substrates according to comparative examples 1 and 2 respectively having thickness of 30□ and 180□ were prepared.

While fabricating the substrate of each embodiment and each comparative example, a horizontal level of the metal tape was measured. In addition, after the substrate of each embodiment and each comparative example was completely fabricated, it was checked whether any crack exists in the upper thin film. Here, the horizontal level was obtained by measuring an angle formed by the metal tape and a virtual line between guide rollers, and the crack existing in the upper thin film was observed using an optical microscope. The measured horizontal level and the presence of crack are listed in the following table 1.

TABLE 1

| | | | | | | | Comparative | |
|---|---|---|---|---|---|---|---|---|
| | | Embodiment | | | | | Example | |
| | | 1 | 2 | 3 | 4 | 5 | 1 | 2 |
| Horizontal Degree (Angle) | | 0° | 0° | 0° | 0° | 0° | 0° | 3° |
| during Deposition | | | | | | | | |
| Upper Thin Film | 1 time | 0 | 0 | 0 | 0 | 0 | 3 | 0 |
| per 1 cm² | 3 times | 0 | 0 | 0 | 0 | 0 | 3 | 0 |
| Number of Cracks | 5 times | 0 | 0 | 0 | 0 | 0 | 2 | 0 |

Seeing the table 1, it is found that the horizontal level is good when the metal tape has a thickness of 40 to 150□, differently from the comparative example 2 that has a horizontal level of 3 degrees, and also no crack is generated in the above range differently from the comparative example 1.

### Experimental Example 2

### Comparison of Formation of Upper Thin Film and Ratio of Texture of the Metal Tape

Using the above fabricating method, substrates according to embodiments 6, 7 and 8 respectively having a ratio of cube texture of 95%, 97% and 99% and substrates according to comparative examples 3, 4 and 5 respectively having a ratio of cube texture of 83%, 87% and 91% were prepared. After that, it was observed from the substrates of each embodiment and each comparative whether any crack exists and whether any anisotropic crystal exists therein. The crack was observed in the same way as in the experimental example 1, and observing an anisotropic crystal was observed using X-ray diffraction pattern. Observation results of crack and anisotropic crystal are listed in the following table 2.

TABLE 2

| | | | | Comparative | | |
|---|---|---|---|---|---|---|
| | Embodiment | | | Example | | |
| | 6 | 7 | 8 | 3 | 4 | 5 |
| Generation of Crack on Upper Thin | X | X | X | ◯ | ◯ | X |
| Film | | | | | | |
| Formation of Anisotropic Cyrstal on | X | X | X | ◯ | ◯ | ◯ |
| Upper Thin Film | | | | | | |

Seeing the table 2, it is found that no crack is generated when a ratio of cube texture is 95% or above, differently from the comparative examples 3 and 4, and no anisotropic crystal is formed in the above range differently from the comparative examples 3, 4 and 5.

### Experimental Example 3

### Relation Between Low-Angle Grain Boundary Ratio of Metal Tape and Crack formed in Upper Thin Film

Using the above fabricating method, substrates according to embodiments 9 and 10 respectively having a ratio of low-angle (not greater than 15 degrees) grain boundary of 99% and 99.8% and substrates according to comparative examples 6 and 7 respectively having a ratio of low-angle (not greater than 15 degrees) grain boundary of 97% and 98% were prepared. After that, it was observed whether any crack exists in the substrate of each embodiment and each comparative example. The crack was observed in the same way as in the experimental example 1. The observation results are listed in the following table 3.

TABLE 3

| | Embodiment | | Comparative Example | |
|---|---|---|---|---|
| | 9 | 10 | 6 | 7 |
| Number of Cracks per 1 cm² | 0 | 0 | 3 | 2 |
| of Upper Thin Film | | | | |

Seeing the Table 3, it was checked that no crack is generated when a ratio of low-angle (not greater than 15 degrees) grain boundary is 99% or above, differently from the comparative examples 6 and 7.

### Experimental Example 4

### Relation Between Size of Grain Forming the Metal Tape and Ratio of Low-Angle Grain Boundary, and Observation of Anisotropic Crystal Formed in Upper Thin Film

Using the above fabricating method, substrates according to embodiments 11, 12, 13 and 14 respectively having an average grain size of 40 □, 60 □, 80□ and 100□ and substrates according to comparative examples 8, 9 and 10 respectively having an average grain size of 20 □, 120□ and 140□ were prepared. After that, a ratio of low-angle grain boundary was measured for each substrate of the embodiments and the comparative examples, and it was observed whether an anisotropic crystal existed in the upper thin film. The ratio of low-angle grain boundary was measured using EBSD, and the anisotropic crystal was observed in the same way as in the experimental example 2. The measured ratio of low-angle grain boundary and the observed result of anisotropic crystal are listed in the following table 4.

TABLE 4

| | | | | | Comparative | | |
|---|---|---|---|---|---|---|---|
| | Embodiment | | | | Example | | |
| | 11 | 12 | 13 | 14 | 8 | 9 | 10 |
| Ratio of Law-angle | 99.5 | 99.7 | 99.4 | 99.1 | 99.2 | 95.8 | 94.7 |
| Grain Boundary (%) | | | | | | | |
| Formation of | X | X | X | X | ◯ | X | X |
| Anisotropic Crystal | | | | | | | |
| on Upper Thin Film | | | | | | | |

Seeing the Table 4, it is found that a ratio of low-angle grain boundary of the upper thin film is high when an average grain size is in the range of 40 to 100□, differently from the comparative examples 9 and 10, and no anisotropic crystal is formed in the above range differently from the comparative example 8.

### Experimental Example 5

### Relation Between Surface Roughness of Metal Tape and Degree of Texture of Upper Thin Film

Using the above fabricating method, substrates according to embodiments 15, 16 and 17 respectively having surface roughness of 10 nm, 30 nm and 50 nm (by RMS) in 100×100 [symbol] of the metal tape and substrate according to comparative examples 11, 12 and 13 respectively having surface roughness of 70 nm, 90 nm and 110 nm (by RMS) in 100×100 [symbol] of the metal tape were prepared. After that, a degree of texture of the upper thin film was observed using X-ray diffraction pattern, and its results are listed in the following table 5.

TABLE 5

| | | | | Comparative | | |
|---|---|---|---|---|---|---|
| | Embodiment | | | Example | | |
| | 15 | 16 | 17 | 11 | 12 | 13 |
| Degree of Texture on Upper Thin | 5° | 5.5° | 6° | 11° | 13° | 16° |
| Film (by FWHM (angle)) | | | | | | |

Seeing the table 5, it is found that, in case a surface roughness in 100×100 [symbol] of the metal tape is 50 nm or less, the embodiments 15, 16 and 17 shows a degree of texture of the upper thin film to be 6 degrees or less in FWHM, which is greatly excellent rather than the comparative examples 11, 12 and 13 that shows 10 degrees or above in FWHM.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

### INDUSTRIAL APPLICABILITY

According to the present invention, since features of grains of a substrate are quantified in various ways, a buffer layer and a superconducting layer may be stably grown without generating a crack or forming an anisotropic crystal, thereby allowing to provide a high-quality superconducting wire.

1. A substrate for a superconducting wire, wherein the substrate is made of Ni or Ni alloy, wherein the substrate has a ratio of cube texture of 95% or above, which is constant in a width direction of a body of the substrate, wherein the substrate has a ratio of low-angle (not greater than 15 degrees) grain boundary of 99% or above, whose distribution is regular in the width direction of the body of the substrate, wherein the substrate has a thickness of 40 to 150 μm, wherein the substrate has an average grain size of 100 μm or less, and wherein the substrate has a surface roughness of RMS (Root Mean Square) 50 nm or less.

2. The substrate for a superconducting wire according to claim 1, wherein the Ni alloy contains Co, Cr, V, Mo, W or B.

3. A method for fabricating a substrate for a superconducting wire, comprising: rolling a Ni or Ni-alloy rod with a rectangular section; and thermally treating the rolled Ni or Ni-alloy rod, wherein the rolling step has a reduction ratio of 5 to 15% at each rolling, wherein the rod is moved between rollers for the rolling process at a linear velocity of 100 m/min or less, and wherein the thermally treating process is conducted by heating at a temperature over a recrystallization temperature together with flowing an inert gas including hydrogen gas.

4. The method for fabricating a substrate for a superconducting wire according to claim 3, wherein the insert gas includes the hydrogen gas at the content of 3 to 5%.

5. A superconducting wire, comprising: a substrate made of Ni or Ni alloy and having a ratio of cube texture of 95% or above, which is constant in a width direction of the substrate, a ratio of low-angle (not greater than 15 degrees) grain boundary of 99% or above, whose distribution is regular in the width direction of the substrate, a thickness of 40 to 150 μm, an average grain size of 100 μm or less, and a surface roughness of RMS 50 nm or less; at least one buffer layer epitaxially laminated on the substrate; and a superconducting layer epitaxially laminated on the buffer layer.

6. The superconducting wire according to claim 5, wherein the buffer layer is composed of ZrO₂, CeO₂, YSZ, Y₂O₃ or HfO₂.

7. The superconducting wire according to claim 5, wherein the buffer layer has three layers laminated from a surface of the substrate in the order of CeO₂, YSZ and CeO₂.

8. The superconducting wire according to claim 5, wherein the buffer layer has three layers laminated from a surface of the substrate in the order of Y₂O₃, YSZ and CeO₂.

9. The superconducting wire according to claim 5, wherein the buffer layer has three layers laminated from a surface of the substrate in the order of CeO₂, YSZ and Y₂O₃.
